(19) United States
(12) Patent Application Publication
(10) Pub. No.: US 2022/0259095 A1
(43) Pub. Date: Aug. 18, 2022

(54) MAGNETIC ADHESION TO THE HOUSEHOLD DEVICE

(71) Applicant: V-Zug AG, Zug (CH)

(72) Inventor: Kilian Hürlimann, Zürich (CH)

(21) Appl. No.: 17/578,732

(22) Filed: Jan. 19, 2022

(30) Foreign Application Priority Data
Jan. 20, 2021 (EP) 21152527.4

(51) Int. Cl. C03C 17/00; C03C 17/32; C03C 17/06; F25D 23/00; H05B 6/12

(52) U.S. Cl. CPC C03C 17/007; C03C 17/326; H05B 6/12; F25D 23/00; C03C 17/06

(57) ABSTRACT

A device, in particular a household device, includes a device housing (1), wherein the device housing (1) is at least partially made of glass (2a). The glass (2a) has a glass outer surface (2h) and a glass inner surface (2g). The device housing (1) is adapted such that a permanent magnet (7) magnetically adheres to the glass outer surface (2h).

### CROSS-REFERENCE TO RELATED APPLICATION

This application claims foreign priority benefits under 35 U.S.C. § 119 to European Patent Application No. 21152527.4 filed on Jan. 20, 2021, the content of which is hereby incorporated by reference in its entirety.

### TECHNICAL FIELD

The invention relates to a device, in particular a household device, having a device housing. The device housing is at least partially made of a glass. The glass has a glass outer surface and a glass inner surface.

### BACKGROUND

There is a need to hang up notes in a kitchen, especially shopping lists or recipes. For example, notes can be sticky notes or they can be magnetically attached to a magnetizable surface by means of a permanent magnet.

Sticky notes have the advantage that they can be arranged on almost any surface. The disadvantage is that the adhesive leaves residues on the surfaces. In contrast, permanent magnets do not leave any residues. However, they can only be attached to magnetizable surfaces.

### SUMMARY

The problem to be solved by the present invention is therefore to extend the possibilities of attaching notes to household devices.

This problem is solved by the subject of the independent claim. Accordingly, a device, in particular a household device, comprises a device housing. A device housing is an enclosure of the device.

The device housing is at least partially made of glass. The glass has a glass outer surface and a glass inner surface. “Inside” and “outside” are to be understood in relation to the device. The outer surface is directed towards the outside of the device, i.e. the glass outer surface is accessible to the user from the outside. The inner surface is directed towards the inside of the device.

Advantageously, the glass is a glass plate with a flat glass outer surface and a flat glass inner surface.

The device housing is adapted such that a permanent magnet magnetically adheres to the glass outer surface.

The advantage is that household devices whose device housing, in particular the front side, is made of glass provide a surface to which notes can be magnetically attached. Additional surfaces are available in a kitchen on which notes can be visibly attached by a permanent magnet.

The outer surface of the glass is the surface of the glass itself. I.e. the note is attached directly to the glass. No further layer is required between the note and the glass to ensure magnetic adhesion.

Advantageously, a coating is arranged on the glass on the inside of the device housing, which coating consists in particular of a magnetizable material. The magnetizable coating has the advantage that a permanent magnet adheres magnetically to the outer surface of the glass.

Device housing inside means that the coating is arranged on the inside of the glass. However, the coating does not necessarily have to be arranged directly on the inner surface of the glass. Advantageously, the coating is arranged directly on the inner surface of the glass. If the coating is not arranged directly on the inner surface of the glass, a non-magnetizable layer, in particular a non-magnetizable paint layer, can be arranged between the coating and the glass, for example.

In particular, the coating is a magnetic paint. This can be printed onto the inner surface of the glass. This allows easy application of the coating to the glass.

In a preferred embodiment, the coating has an epoxy- or acrylic-based matrix. In particular, the matrix is thermostable up to a temperature of 200° C., in particular 250° C. This thermostability is ensured, for example, by epoxy resins known to those skilled in the art. This allows the coating to be applied even in places where high temperatures exist during operation of the device, for example in an oven.

Advantageously, the coating comprises iron pigments, i.e. in particular the epoxy or acrylic based matrix encloses the iron pigments. This makes the coating magnetizable. In particular, the coating is ferromagnetic.

Advantageously, the coating has a thickness of at least 0.3 mm, in particular at least 0.5 mm, in particular at least 0.8 mm, in particular at least 1.0 mm. The thicker the coating is applied, the more strongly a permanent magnet adheres to the outer surface of the glass.

In particular, the coating has the shape of a frame. This frame is intended to frame a transparent glass surface. Such a design is advantageous, for example, in the case of an oven door. The oven door has a frame colored with the magnetic paint, which has a good visual effect and to which permanent magnets adhere. At the same time, the frame encloses an area of the glass on which no paint is applied. This area is thus transparent and the user can see through this transparent area from the outside into the interior of the oven.

If the coating is arranged on the glass inner surface of an oven door, as mentioned, this may be the outer glass of a double-glazed oven door. Thus, the coating is protected from the high temperatures existing in the oven.

In particular, the household device is an oven, a microwave oven or a steam cooking device. As mentioned, the coating may be arranged on the device door. Alternatively, other components of the device housing may be formed of glass, such as the control panel, to which permanent magnets may adhere.

Furthermore, the household device can be a cooling device, in particular a refrigerator, a wine refrigerator or a freezer. In particular, in the case of wine refrigerators, it is preferred that the door be made of glass so that the user can look into the interior of the wine refrigerator from the outside.

Furthermore, the coating can also be arranged on a cooktop. This would allow a permanent magnet to adhere to a glass ceramic cooktop, for example.

### BRIEF DESCRIPTION OF THE DRAWINGS

Further embodiments, advantages and applications of the invention will be apparent from the dependent claims and from the description which now follows with reference to the figures. Thereby show:

FIG. 1 a cooking device with a device door;

FIG. 2a the front side of the device door with view from the outside;

FIG. 2b the inside of the outer glass panel of the device door;

FIG. 3a a sectional view of a front portion of an oven with the door closed; and

FIG. 3b the oven of FIG. 3a with the door open.

### DETAILED DESCRIPTION

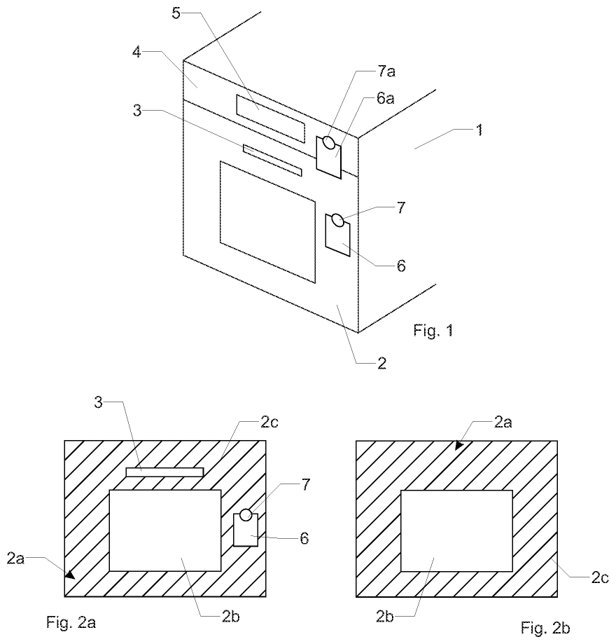

FIG. 1 shows an oven with a device housing 1. Alternatively, it could also be a microwave, a steam oven or another household device. The oven comprises n device door 2, which is part of the device housing 1. A door handle 3 is arranged on the device door 2. By opening and closing the device door, the user gains access to the cooking chamber of the oven. A panel 4 with a control display 5 is arranged above the device door 2. The control display 5 is a touch-sensitive control display, i.e. the user can control the oven by touching the control display 5. Both the device door 2 and the panel 4 are made of glass on the front side.

A note 6 is attached to the front of the device door 2 by means of a permanent magnet 7. It is now described in more detail how the device door 2 must be designed so that the permanent magnet 7 adheres magnetically to the front side of the device door 2.

Furthermore, a second note 6a is also arranged on the front side of the panel 4 by means of a second note 7a.

FIG. 2a shows the device door 2 with front view from the outside. On its outside, the device door 2 has a glass plate 2a. This glass plate 2a extends over the entire area shown in FIG. 2a, i.e. over both the hatched area and the white framed area. It is covered only by the door handle 3, the note 6 and the permanent magnet 7. In the central area 2b, the device door 2 is transparent, i.e. the user can look into the cooking chamber through the central area 2b. The central area 2b is framed by a black area 2c. This area is shown hatched. The area 2c appears black because on the back of the glass plate 2a, the area 2c is coated with a dark color. The back side of the glass plate 2a is shown in FIG. 2b.

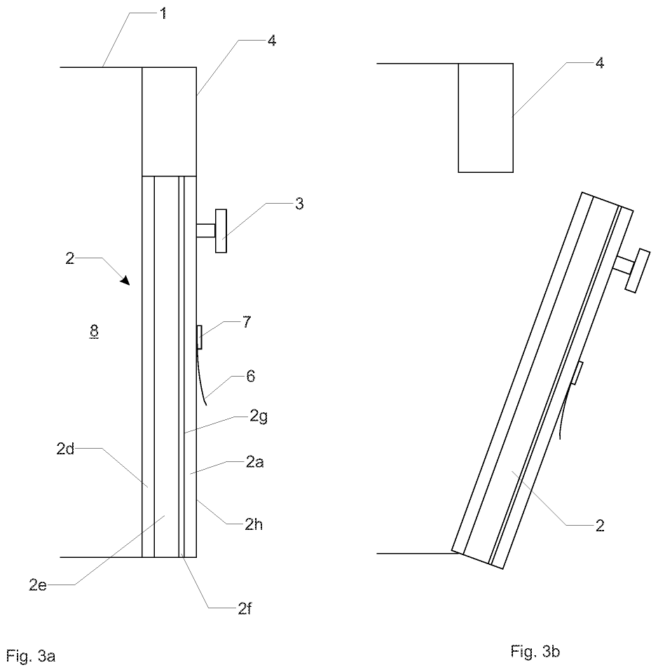

FIGS. 3a and 3b show a sectional view through the oven. The device door 2 and the panel 4 are visible. The door handle 3 is also visible on the front side. The device door 2 has double glazing. Towards the outside, the glass plate 2a is arranged on the device door, which is, for example, a float glass or a normal flat glass. A second glass plate 2d is arranged towards the interior of the oven. Between the glass plate 2a and the second glass plate 2d is the glass interspace 2e. This glass interspace 2e is hermetically sealed and provides good thermal insulation. Also visible is the note 6 attached to the front side with the permanent magnet 7.

The outer glass plate 2a has a glass inner surface 2g and a glass outer surface 2h. A coating 2f is disposed on the glass inner surface 2g. This coating 2f is made of a magnetizable material. It is a magnetic ink which has been printed directly on the glass inner surface 2g of the outer glass plate 2a in a printing process. The coating has a thickness of 1 mm as an example. The outer glass plate 2a has a thickness of 3 mm as an example.

The magnetic ink of this embodiment has an acrylic dispersion to which iron pigments have been added. When a permanent magnet approaches the glass plate 2a from the outside, the coating 2f is magnetized and the permanent magnet magnetically adheres to the glass outer surface 2h of the glass plate 2a. By varying the thickness of the coating 2f and the thickness of the glass plate 2a, the attraction force of the permanent magnet 7 to the front surface of the glass plate 2a can be adjusted.

While preferred embodiments of the invention are described in the present application, it should be clearly noted that the invention is not limited thereto and may be carried out in other ways as well within the scope of the following claims.

What is claimed is:

1. A device, in particular a household device, having a device housing, the device housing consisting at least partially of glass and the glass having a glass outer surface and a glass inner surface,
wherein the device housing is adapted such that a permanent magnet magnetically adheres to the glass outer surface.

2. The household device according to claim 1, wherein a coating is arranged on the inside of the device housing on the glass.

3. The household device according to claim 2, wherein coating consists of a magnetizable material.

4. The household device according to claim 2, wherein the coating is a magnetic paint.

5. The household device according to claim 2, wherein the coating comprises an epoxy- or acrylic-based matrix.

6. The household device according to claim 5, wherein the matrix is thermostable up to a temperature of 200° C.

7. The household device according to claim 5, wherein the matrix is thermostable up to a temperature of 250° C.

8. The household device according to claim 2, wherein the coating comprises iron pigments.

9. The household device according to claim 2, wherein the coating is ferromagnetic.

10. The household device according to claim 2, wherein the coating is arranged directly on the glass inner surface.

11. The household device according to claim 2, wherein a non-magnetizable layer is arranged between the glass and the coating.

12. The household device according to claim 11, wherein the non-magnetizable layer is a paint layer,

13. The household device according to claim 2, wherein the coating has a thickness of at least 0.3 mm, in particular at least 0.5 mm, in particular at least 0.8 mm, in particular at least 1.0 mm.

14. The household device according to claim 2, wherein the coating has the shape of a frame and frames a transparent glass surface.

15. The household device according to claim 1, wherein the glass is part of a device door.

16. The household device according to claim 15, wherein the glass is an outer glass of a double-glazed device door.

17. The household device according to claim 1, wherein the household device is
a cooking device, in particular an oven, a microwave or a steam cooking device, or
a cooling device, in particular a refrigerator, a wine refrigerator or a freezer, or
a cooktop.
